(19) United States
(12) Patent Application Publication
(10) Pub. No.: US 2026/0090152 A1
(43) Pub. Date: Mar. 26, 2026

(54) DISPLAY DEVICE

(71) Applicant: AUO Corporation, Hsinchu City (TW)

(72) Inventor: Tzu-Chin Huang, Hsinchu City (TW)

(73) Assignee: AUO Corporation, Hsinchu City (TW)

(21) Appl. No.: 18/945,541

(22) Filed: Nov. 13, 2024

(30) Foreign Application Priority Data
Sep. 25, 2024 (TW) 113136262

(51) Int. Cl. H01L 33/58; H01L 33/50

(52) U.S. Cl. CPC H10H 20/855; H10H 20/8512; H10H 20/882

(57) ABSTRACT

A display device including multiple display pixels. Each display pixel includes a first display unit. The first display unit includes a first light-emitting element, a color conversion layer, a first color filter layer, and a first optical structure. The first light-emitting element is disposed on an inner surface of a lower substrate of the display device. The color conversion layer covers the first light-emitting element. The first color filter layer is disposed on an inner surface of an upper substrate of the display device. The first optical structure has refractive power. The first color filter layer is disposed between the upper substrate and the first optical structure. A light entrance surface and a light-emitting surface of the first color filter layer are not a plane.

### CROSS-REFERENCE TO RELATED APPLICATION

This application claims the priority benefit of Taiwan application serial no. 113136262, filed on Sep. 25, 2024. The entirety of the above-mentioned patent application is hereby incorporated by reference herein and made a part of this specification.

### BACKGROUND

### Technical Field

This disclosure relates to a display device.

### Description of Related Art

Currently, display devices on the market are equipped with a microlens structure in the upper plate structure to improve the forward light output. However, a color filter layer process after the process of the microlens causes cracking and discoloration of the microlens structure.

Therefore, in some display devices, the color filter layer is configured first and the microlens structure is configured later. However, in such a manufacturing method, the microlens structure is configured between the color filter layer and the light-emitting element, resulting in a larger distance between the color filter layer and the light-emitting element, and thus a problem of a restricted viewing angle occurs.

### SUMMARY

The disclosure provides a display device with a large viewing angle and good optical performance.

According to an embodiment of the disclosure, a display device including multiple display pixels is provided. Each of the display pixels includes a first display unit, and the first display unit includes a first light-emitting element, a color conversion layer, a first color filter layer, and a first optical structure. The first light-emitting element is disposed on an inner surface of a lower substrate of the display device. The color conversion layer covers the first light-emitting element. The first color filter layer is disposed on an inner surface of an upper substrate of the display device. The first optical structure has refractive power, where the first color filter layer is located between the upper substrate and the first optical structure. The inner surface of the upper substrate faces the inner surface of the lower substrate. A light entrance surface and a light-emitting surface of the first color filter layer are not a plane.

Based on the above, the display device provided by the embodiment of the disclosure includes multiple display units. Each display unit includes an optical structure with refractive power and a color filter layer. The light entrance surface and the light-emitting surface of the color filter layer are not a plane. The display device provided by the embodiment of the disclosure may avoid cracking and discoloration of the optical structure during the manufacturing process, and may provide a large viewing angle.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate example embodiments of the disclosure and, together with the description, serve to explain the principles of the disclosure.

FIG. 1 shows a schematic diagram of a display device according to a first embodiment of the disclosure.

FIG. 2 shows a schematic diagram of a display device according to a second embodiment of the disclosure.

FIG. 3 shows a schematic diagram of a display device according to a third embodiment of the disclosure.

FIG. 4 shows a schematic diagram of a display device according to a fourth embodiment of the disclosure.

FIG. 5 shows a schematic diagram of a display device according to a fifth embodiment of the disclosure.

### DESCRIPTION OF THE EMBODIMENTS

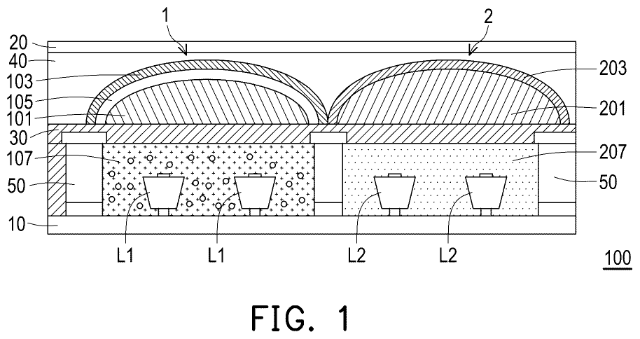

Referring to FIG. 1, FIG. 1 shows a schematic diagram of a display device according to a first embodiment of the disclosure. A display device 100 includes a lower substrate 10, an upper substrate 20, and multiple display pixels disposed between an inner surface of the lower substrate 10 and an inner surface of the upper substrate 20. Each display pixel includes a first display unit 1 and a second display unit 2, where the first display unit 1 can be used to generate red light or green light, and the second display unit 2 is used to generate blue light. Although not shown in the figure, each display pixel may also include a third display unit, which is used to generate color light different from the first display unit 1 and the second display unit 2.

The first display unit 1 includes a first light-emitting element L1, a color conversion layer 107, a first color filter layer 103, a first optical structure 101, and a first dielectric layer 105. The second display unit 2 includes a second light-emitting element L2, a second color filter layer 203, and a second optical structure 201. It should be noted that the first display unit 1 may only include one first light-emitting element L1, and the second display unit 2 may only include one second light-emitting element L2, and is not limited to the architecture shown in FIG. 1.

In the lower plate structure of FIG. 1, the first light-emitting element L1 may be, for example, an ultraviolet light-emitting diode or a blue light-emitting diode. The color conversion layer 107 covering the first light-emitting element L1 can absorb the light emitted by the first light-emitting element L1 to generate red light or green light. The color of the first color filter layer 103 corresponds to the color conversion layer 107. The second light-emitting element L2 may be a blue light-emitting diode. The second display unit 2 may also include a scattering layer 207 covering the second light-emitting element L2 to facilitate light uniformity, but is not limited thereto. A bank 50 can be disposed between the color conversion layer 107 and the scattering layer 207 to avoid crosstalk between the first display unit 1 and the second display unit 2.

In a manufacturing method of display device according to the embodiment of the disclosure, a buffer layer 40 may be disposed on the inner surface of the upper substrate 20; after a part of the buffer layer 40 is removed, the first color filter layer 103 and the second color filter layer 203 are disposed on the exposed buffer layer 40; the first dielectric layer 105 and the first optical structure 101 are sequentially disposed on the first color filter layer 103; and the second optical structure 201 is disposed on the second color filter layer 203. Accordingly, the upper plate structure shown in FIG. 1 can be completed.

It should be noted that the process of configuring the first color filter layer 103 and the second color filter layer 203 is usually a high-temperature process, and the process temperature may be higher than 200 degrees Celsius. However, the withstand temperatures of the first optical structure 101 and the second optical structure 201 fall below 90 degrees. Therefore, the process sequence of first configuring the first color filter layer 103 and the second color filter layer 203 and then configuring the first optical structure 101 and the second optical structure 201 avoids cracking and discoloration of the first optical structure 101 and the second optical structure 201. It should also be noted that in the display device produced through the above process sequence, each color filter layer and the corresponding light-emitting element are located on the opposite side of the optical structure. In other words, the distance between the color filter layer and the light-emitting element becomes larger, so there may be a problem of restricted viewing angle.

Referring again to FIG. 1, the first optical structure 101 and the second optical structure 201 of this embodiment have an outline like a convex lens, which can condense light and improve the forward light output of the display device 100. In addition, the curved surface of the convex lens profile corresponds to a 180-degree viewing angle. The first color filter layer 103 and the second color filter layer 203 have curved surfaces, which also correspond to a 180-degree viewing angle. Accordingly, the display device 100 provided in this embodiment can significantly increase the viewing angle compared with the conventional display device equipped with a plane color filter layer. In addition, the first color filter layer 103 is adjacent to the second color filter layer 203 to avoid large-angle chromatic aberration and energy loss. In summary, the display device 100 provided in this embodiment completely avoids the problem of restricted viewing angle by setting the first color filter layer 103 and the second color filter layer 203 in a non-plane form and using the first optical structure 101 and the second optical structure 201 with light gathering function.

It should be noted that the refractive index of the first optical structure 101 is configured to be greater than the refractive index of the first dielectric layer 105, which is conducive to total reflection occurring at the interface between the two. The light reflected back to the lower plate structure can pass through the color conversion layer 107 again, improving the color conversion rate and improving the current efficiency of the first display unit 1.

It should also be noted that the refractive index of the second optical structure 201 is configured to be greater than the refractive index of the second color filter layer 203. In this way, light can be concentrated toward the forward viewing angle at the interface between the two, thereby improving the forward light output of the display device 100.

The display device 100 of this embodiment also includes a filling layer 30, which is disposed between the color conversion layer 107 and the first optical structure 101, and between the second light-emitting element L2 and the second optical structure 201. The refractive index of the filling layer 30 may be less than or equal to the refractive index of the color conversion layer 107, the refractive index of the first optical structure 101, the refractive index of the first dielectric layer 105, the refractive index of the second optical structure 201, and the refractive index of the scattering layer 207. Accordingly, total reflection can occur at the interface between the filling layer 30 and the color conversion layer 107 and the scattering layer 207, and large-angle light can be recovered. Light returning to the color conversion layer 107 can be color converted again. Moreover, total reflection at the interface between the upper substrate 20 and the air can be avoided.

In this embodiment, the interface between the first optical structure 101 and the first dielectric layer 105 (i.e., the first surface of the first dielectric layer 105) and the interface between the first dielectric layer 105 and the first color filter layer 103 (i.e., the second surface of the first dielectric layer 105) are conformal, but not limited thereto. In addition, the refractive index of the buffer layer 40 is less than the refractive index of the first optical structure 101 and the refractive index of the second optical structure 201, so that the light can be concentrated toward the forward viewing angle. In addition, the refractive index of the buffer layer 40 is also less than the refractive index of the first color filter layer 103 and the refractive index of the second color filter layer 203.

In order to fully illustrate various implementation aspects of the disclosure, other embodiments of the disclosure are described below. It should be noted here that the following embodiments follow the reference numerals and part of the content of the previous embodiments, where the same reference numerals are used to represent the same or similar elements, and descriptions of the same technical content are omitted. For descriptions of omitted parts, reference may be made to the foregoing embodiments and will not be repeated in the following embodiments.

Referring to FIG. 2, FIG. 2 shows a schematic diagram of a display device according to a second embodiment of the disclosure. A display device 200 of the second embodiment is different from the display device 100 of the first embodiment in that the interface (i.e., the first surface of the first dielectric layer 105) between the first optical structure 101 and the first dielectric layer 105 and the interface (i.e., the first surface of the second dielectric layer 105) between the first dielectric layer 105 and the first color filter layer 103 are not conformal. The curve formed by the first surface in the cross-sectional view shown in FIG. 2 has a first radius of curvature, and the curve formed by the second surface in the cross-sectional view shown in FIG. 2 has a second radius of curvature, where the first radius of curvature is less than the second radius of curvature. In this way, the first optical structure 101 that provides the light gathering function can have sufficient refractive power, and the first color filter layer 103 has a lower degree of curvature and a higher structural stability.

The difference between the display device 200 and the display device 100 is further in that a second dielectric layer 205 is disposed between the second optical structure 201 and the second color filter layer 203. The interface between the second optical structure 201 and the second dielectric layer 205 and the interface between the second dielectric layer 205 and the second color filter layer 203 are not conformal. The second optical structure 201 that provides light gathering function can have sufficient refractive power, and the second color filter layer 203 has a lower degree of curvature and a higher structural stability.

In addition, the refractive index of the second dielectric layer 205 is configured to be greater than the refractive index of the second color filter layer 203 and less than or equal to the refractive index of the second optical structure 201. Accordingly, the light can be concentrated toward the forward viewing angle, thereby improving the forward light output of the display device 100. In this embodiment, the refractive index of the filling layer 30 may be less than or equal to the refractive index of the color conversion layer 107, the refractive index of the first optical structure 101, the refractive index of the first dielectric layer 105, the refractive index of the second optical structure 201, the refractive index of the second dielectric layer 205, and the refractive index of the scattering layer 207. Accordingly, total reflection can occur at the interface between the filling layer 30 and the color conversion layer 107 and the scattering layer 207, and large-angle light can be recovered. Light returning to the color conversion layer 107 can be color converted again. Moreover, total reflection at the interface between the upper substrate 20 and the air can be avoided.

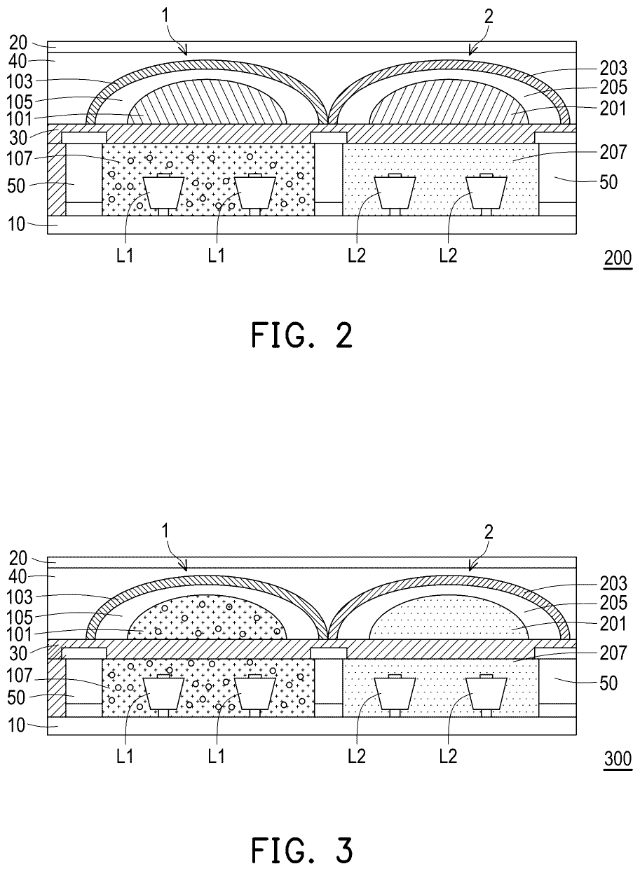

Referring to FIG. 3, FIG. 3 shows a schematic diagram of a display device according to a third embodiment of the disclosure. A display device 300 of the third embodiment is different from the display device 200 of the second embodiment in that the material of the first optical structure 101 is configured to be the same as the material of the color conversion layer 107 and thus has color conversion capability, and the material of the second optical structure 201 is configured to be the same as the material of the color conversion layer 207 and thus has light uniformity capability. In this way, in addition to having the ability to gather light due to its convex lens profile, the first optical structure 101 can also perform color conversion when light passes through the first optical structure 101, improving the color conversion rate and improving the current efficiency of the first display unit 1. Moreover, in addition to having the ability to gather light due to its convex lens profile, the second optical structure 201 can also perform light uniformity. Therefore, the color conversion layer 107 and the scattering layer 207 in the display device 300 may be thinner than the color conversion layer 107 and the scattering layer 207 in the display device 200. In other words, the display device 300 may have a smaller overall thickness than the display device 200.

Referring to FIG. 4, FIG. 4 shows a schematic diagram of a display device according to a fourth embodiment of the disclosure. A display device 400 of the fourth embodiment is different from the display device 100 of the first embodiment in that the first color filter layer 103 includes a first part 103C and a second part 103P, the first part 103C of the first color filter layer 103 has a curved surface, and the second part 103P of the first color filter layer 103 has a plane; the second color filter layer 203 includes a first part 203C and a second part 203P, the first part 203C of the second color filter layer 203 has a curved surface, and the second part 203P of the second color filter layer 203 has a plane.

In a manufacturing method of display device according to the embodiment of the disclosure, a first buffer layer 401 may be disposed on the inner surface of the upper substrate 20; after a part of the first buffer layer 401 is removed, the first part 103C of the first color filter layer 103 and the first part 203C of the second color filter layer 203 are disposed on the exposed first buffer layer 401, and the second part 103P of the first color filter layer 103 and the second part 203P of the second color filter layer 203 are disposed on the top surface of the first buffer layer 401, where the second part 103P surrounds the first part 103C, the second part 203P surrounds the first part 203C, and the second part 103P is adjacent to the second part 203P; a second buffer layer 402 is disposed on the first color filter layer 103, the second color filter layer 203, and the first buffer layer 401; and after a part of the second buffer layer 402 is removed, the first optical structure 101 and the second optical structure 201 are disposed on the exposed second buffer layer 402. Accordingly, the upper plate structure shown in FIG. 4 can be completed.

In this embodiment, the first part 103C of the first color filter layer 103 and the first part 203C of the second color filter layer 203 have curved surfaces, and the curved surfaces correspond to a viewing angle of at least 160 degrees. The second part 103P of the first color filter layer 103 and the second part 203P of the second color filter layer 203 have a plane, which has high structural stability and can correspond to a viewing angle of at least 160 degrees to 170 degrees to avoid large-angle chromatic aberration and energy loss.

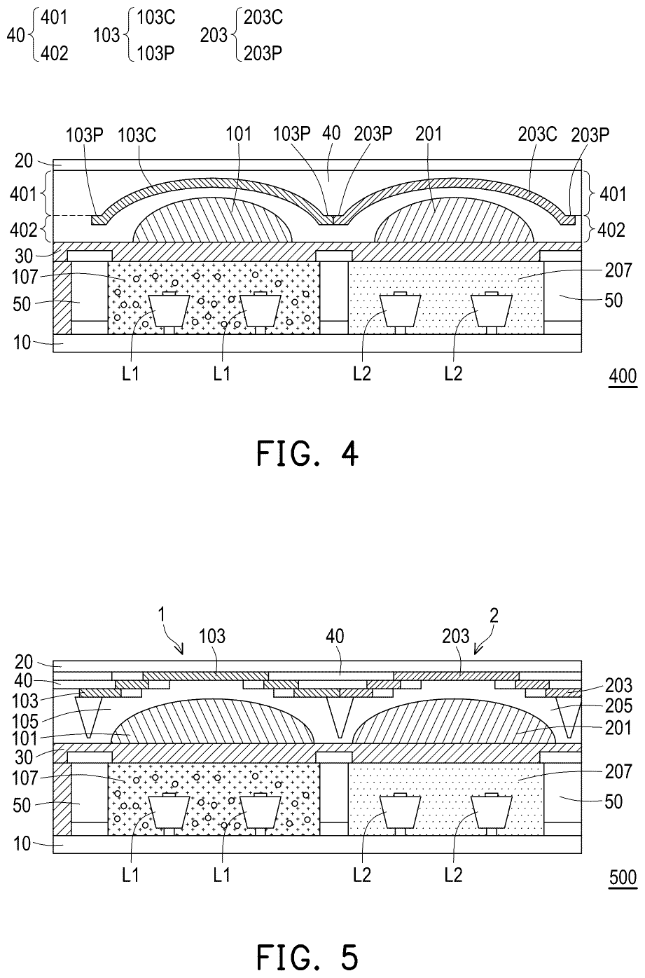

Referring to FIG. 5, FIG. 5 shows a schematic diagram of a display device according to a fifth embodiment of the disclosure. A display device 500 of the fifth embodiment is different from the display device 100 of the first embodiment in that the light entrance surface and light-emitting surface of the first color filter layer 103 have step-shaped surfaces, and the light entrance surface and light-emitting surface of the second color filter layer 203 have step-shaped surfaces, where the light entrance surface refers to the surface of the color filter layer facing the corresponding light-emitting element, and the light-emitting surface refers to the surface of the color filter layer facing away from the corresponding light-emitting element.

In a manufacturing method of display device according to the embodiment of the disclosure, the first color filter layer 103 and the second color filter layer 203 as shown in FIG. 5 may be produced by periodically repeating a process of configuring a buffer layer on the inner surface of the upper substrate 20, a process of removing a part of the buffer layer, and a process of configuring a color filter layer on the exposed buffer layer.

Since the first color filter layer 103 and the second color filter layer 203 in FIG. 5 can be regarded as consisting of multiple plane structures on different layers, they can have good structural stability. Moreover, compared with the display device in the prior art that only has a single layer of plane color filter layer, the display device 500 of according to the fifth embodiment may greatly increase the viewing angle.

To sum up, the display device provided by the embodiment of the disclosure includes multiple display units. Each display unit includes an optical structure with refractive power and a color filter layer. The light entrance surface and the light-emitting surface of the color filter layer are a not plane. The display device provided by the embodiment of the disclosure may avoid cracking and discoloration of the optical structure during the manufacturing process, and may provide a large viewing angle.

It will be apparent to those skilled in the art that various modifications and variations can be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A display device, comprising a plurality of display pixels, wherein each of the display pixels comprises a first display unit, and the first display unit comprises:
a first light-emitting element, disposed on an inner surface of a lower substrate of the display device;
a color conversion layer, covering the first light-emitting element;
a first color filter layer, disposed on an inner surface of an upper substrate of the display device; and
a first optical structure, having refractive power, wherein the first color filter layer is located between the upper substrate and the first optical structure,
wherein the inner surface of the upper substrate faces the inner surface of the lower substrate, and a light entrance surface and a light-emitting surface of the first color filter layer are not a plane.

2. The display device according to claim 1, further comprising a first dielectric layer disposed between the first optical structure and the first color filter layer, wherein a refractive index of the first optical structure is greater than a refractive index of the first dielectric layer.

3. The display device according to claim 2, wherein the refractive index of the first dielectric layer is less than a refractive index of the first color filter layer.

4. The display device according to claim 1, wherein the first color filter layer comprises a first part and a second part, the first part has a curved surface, and the second part has a plane.

5. The display device according to claim 1, further comprising a first dielectric layer disposed between the first optical structure and the first color filter layer, wherein the first dielectric layer has a first surface adjacent to the first optical structure and a second surface adjacent to the first color filter layer, and the first surface and the second surface are not conformal.

6. The display device according to claim 1, further comprising a first dielectric layer disposed between the first optical structure and the first color filter layer, wherein the first dielectric layer has a first surface adjacent to the first optical structure and a second surface adjacent to the first color filter layer, and the first surface and the second surface are conformal.

7. The display device according to claim 1, further comprising a filling layer disposed between the color conversion layer and the first optical structure, wherein a refractive index of the filling layer is less than a refractive index of the color conversion layer.

8. The display device according to claim 7, further comprising a first dielectric layer disposed between the first optical structure and the first color filter layer, wherein the refractive index of the filling layer is less than a refractive index of the first dielectric layer.

9. The display device according to claim 1, further comprising a buffer layer disposed between the first color filter layer and the upper substrate, wherein a refractive index of the buffer layer is less than a refractive index of the first color filter layer.

10. The display device according to claim 1, wherein a material of the first optical structure is the same as a material of the color conversion layer.

11. The display device according to claim 1, wherein the light entrance surface and the light-emitting surface of the first color filter layer have step-shaped surfaces.

12. The display device according to claim 1, wherein the each of the display pixels further comprises a second display unit, and the second display unit comprises:
a second light-emitting element, disposed on the inner surface of the lower substrate;
a second color filter layer, disposed on the inner surface of the upper substrate; and
a second optical structure, disposed on the inner surface of the upper substrate and having refractive power, wherein the second color filter layer is located between the upper substrate and the second optical structure,
wherein a light entrance surface and a light-emitting surface of the second color filter layer are not a plane.

13. The display device according to claim 12, further comprising a scattering layer covering the second light-emitting element, and a material of the second optical structure is the same as a material of the scattering layer.

14. The display device according to claim 12, wherein the second optical structure comprises a scattering layer.

15. The display device according to claim 12, wherein a refractive index of the second optical structure is greater than a refractive index of the second color filter layer.

16. The display device according to claim 12, further comprising a second dielectric layer disposed between the second optical structure and the second color filter layer, wherein a refractive index of the second dielectric layer is greater than a refractive index of the second color filter layer and is less than a refractive index of the second optical structure.

17. The display device according to claim 13, further comprising a filling layer disposed between the scattering layer and the second optical structure, wherein a refractive index of the filling layer is less than or equal to a refractive index of the scattering layer.

18. The display device according to claim 17, further comprising a second dielectric layer disposed between the second optical structure and the second color filter layer, wherein the refractive index of the filling layer is less than or equal to a refractive index of the second dielectric layer.

19. The display device according to claim 12, wherein the first color filter layer is adjacent to the second color filter layer.

20. The display device according to claim 12, wherein the first color filter layer comprises a first part and a second part, the first part of the first color filter layer has a curved surface, and the second part of the first color filter layer has a plane; the second color filter layer comprises a first part and a second part, the first part of the second color filter layer has a curved surface, and the second part of the second color filter layer has a plane.
